(19) United States
(12) Patent Application Publication
(10) Pub. No.: US 2026/0047153 A1
(43) Pub. Date: Feb. 12, 2026

(54) POWER ELEMENT AND MANUFACTURING METHOD FOR THE SAME

(71) Applicants: NIKO SEMICONDUCTOR CO., LTD., NEW TAIPEI CITY (TW); SUPER GROUP SEMICONDUCTOR CO., LTD., Hsinchu County (TW)

(72) Inventors: SUNG-NIEN TANG, HSINCHU COUNTY (TW); HO-TAI CHEN, Hsinchu County (TW); HSIU-WEN HSU, Hsinchu County (TW)

(21) Appl. No.: 18/973,178

(22) Filed: Dec. 9, 2024

(30) Foreign Application Priority Data
Aug. 8, 2024 (TW) 113129654

(51) Int. Cl. H10D 62/10; H01L 21/265; H10D 30/01; H10D 30/66; H10D 62/832; H10D 64/66

(52) U.S. Cl. CPC H10D 62/107; H01L 21/26506; H10D 30/0297; H10D 30/668; H10D 64/661; H10D 62/8325

(57) ABSTRACT

A power element and a manufacturing method for the power element are provided. The power element that is manufactured is a trench-type metal oxide semiconductor field-effect transistor having a junction field-effect transistor region. The power element includes a substrate, a drift diffusion layer, a body layer, a plurality of gate trenches, polycrystalline silicon, a plurality of first doped regions, a plurality of second doped regions, a plurality of protective doped regions, a plurality of dielectric layers, and a metal conductive layer.

### CROSS-REFERENCE TO RELATED PATENT APPLICATION

This application claims the benefit of priority to Taiwan Patent Application No. 113129654, filed on Aug. 8, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor element, and more particularly to a power element having a junction field-effect transistor region.

### BACKGROUND OF THE DISCLOSURE

Metal oxide semiconductor field-effect transistors (MOSFETs) are widely used in power switch elements. In recent years, trench silicon carbide (SiC) technology has been proposed for use in the field of electric vehicles and solar inverters. Among MOSFETs used for electric power, in trench-type MOSFETs, side surfaces of trenches formed on the surface of a semiconductor chip are used as channels. In this way, the channel width and density can be increased and the performance of the element can be improved.

However, when the power element used as a switch is in an off-state (OFF), the electric field at the bottom of the trench is concentrated. Specifically, at the corners of the trench, the electric field is large, and the voltage resistance of the power element is insufficient. In the on-state (ON) of the power element, the resistance of the trench is high, such that electric current cannot easily flow from the source to the drain, and the power element is ineffective.

Therefore, how to improve the performance of power elements through improvements in structural design to overcome the above-mentioned defects, has become one of the important issues to be addressed in this industry.

### SUMMARY OF THE DISCLOSURE

In response to the above-referenced technical inadequacies, the present disclosure provides a power element and a manufacturing method for a power element.

In order to solve the above-mentioned problems, one of the technical aspects adopted by the present disclosure is to provide a manufacturing method for a power element. The manufacturing method for the power element includes steps as follows: providing a substrate, the substrate being doped with a first conductive dopant, the substrate having a top surface, a drift diffusion layer being formed on the top surface, and the drift diffusion layer being doped with the first conductive dopant; forming a body layer having a second conductive dopant on the drift diffusion layer; implanting a surface of the body layer, so that the first conductive dopant having a high concentration is used for doping to form a plurality of first doped regions, and implanting the surface of the body layer, so that the second conductive dopant having a high concentration is used for doping to form a plurality of second doped regions, any of the plurality of second doped regions being located between two adjacent ones of the plurality of first doped regions; forming a plurality of trenches, each of the plurality of trenches respectively corresponding to each of the plurality of first doped regions, and each of the plurality of trenches extending downward from a surface of the body layer into the body layer; respectively disposing a plurality of hard masks on parts of the surface of the body layer that do not have the plurality of trenches; depositing a first oxide in each of the plurality of trenches, the first oxide filling the plurality of trenches; removing a central region of each of the first oxides to form a slot, the slot extending to a bottom wall of the trench; implanting the first conductive dopant in each of the slots to form a protective doped region under the slot, the protective doped region extending to the surface of the drift diffusion layer; a first region and a second region being respectively defined on two sides of the protective doped region, and the first region, the protective doped region, and the second region being located between the bottom wall of the trench and the surface of the drift diffusion layer to form a junction field-effect transistor region; depositing an oxide layer composed of a second oxide on each of the plurality of trenches to form a plurality of gate trenches; doping polycrystalline silicon into each of the plurality of gate trenches to form a gate region; forming a plurality of dielectric layers on the plurality of gate trenches, respectively; forming a metal conductive layer on the body layer, the metal conductive layer covering each of the plurality of dielectric layers, each of the plurality of first doped regions, and each of the plurality of second doped regions.

In one of the possible or preferred embodiments, the process of forming the body layer includes implanting the second conductive dopant, or using the second conductive dopant for doping on the drift diffusion layer to form an epitaxial layer.

In one of the possible or preferred embodiments, from a top view, each of the plurality of trenches extends along a first direction to define a first trench, and the manufacturing method for the power element further comprises forming a plurality of additional trenches, each of the plurality of additional trenches extends along a second direction to define a second trench; in which a junction area is defined on an intersection of each of the first trenches and each of the second trenches; in which, in the process of removing a central region of each of the first oxides to form a slot, the slot does not extend to the bottom wall of the trench within the junction area.

In order to solve the above-mentioned problems, another one of the technical aspects adopted by the present disclosure is to provide a power element. The power element includes a substrate, a drift diffusion layer, a body layer, a plurality of gate trenches, polycrystalline silicon, a plurality of first doped regions, a plurality of second doped regions, a plurality of protective doped regions, a plurality of dielectric layers, and a metal conductive layer. The substrate has a first conductive dopant. The drift diffusion layer is located on a top surface of the substrate. The drift diffusion layer has the first conductive dopant. The body layer is located on the drift diffusion layer. The body layer has a second conductive dopant, and an implantation surface is defined on a surface of the body layer. Each of the gate trenches has two side oxide layers and a bottom oxide layer. The polycrystalline silicon is respectively filled in each of the plurality of gate trenches to form a plurality of gate regions. The plurality of first doped regions are located under the implantation surface and respectively located on two sides of each of the gate trenches. Each of the plurality of first doped regions has a high concentration of the first conductive dopant. The plurality of second doped regions are located under the implantation surface. Each of the plurality of second doped regions is located between two adjacent ones of the plurality of first doped regions, and each of the plurality of second doped regions has a high concentration of the second conductive dopant. The plurality of protective doped regions are located in the body layer. Two ends of each of the plurality of protective doped regions are respectively connected to a bottom wall of a corresponding one of the gate trenches and the surface of the drift diffusion layer. A first region and a second region are respectively defined on two sides of each of the plurality of protective doped region, and the first region, the protective doped region, and the second region are located between the bottom wall of the gate trench and the surface of the drift diffusion layer to form a junction field-effect transistor region. The plurality of dielectric layers are located on the plurality of gate trenches, respectively. The metal conductive layer is located on the body layer. The metal conductive layer covers each of the plurality of dielectric layers, each of the plurality of first doped regions, and each of the plurality of second doped regions.

In one of the possible or preferred embodiments, the body layer is a well layer or an epitaxial layer.

In one of the possible or preferred embodiments, a concentration of the protective doped region is greater than a concentration of the body layer, and the concentration of the body layer is greater than a concentration of the drift diffusion layer.

In one of the possible or preferred embodiments, the substrate is a silicon carbide substrate, the first conductive dopant is an N-type dopant, and the second conductive dopant is a P-type dopant.

Therefore, in the power element and the manufacturing method for the power element provided by the present disclosure, by virtue of “forming a plurality of trenches,” “implanting the first conductive dopant in each of the slots to form a protective doped region under the slot,” and “the first region, the protective doped region, and the second region form a junction field-effect transistor region,” a manufacturing process of the power element can be simplified, and a doping concentration of the entire protective doped region is more uniform.

Furthermore, in the power element and the manufacturing method for the power element provided by the present disclosure, by virtue of “the first region, the protective doped region, and the second region of the power element form a junction field-effect transistor region,” the junction field-effect transistor region in an off-state can decrease an electric field at a bottom portion of the gate trenches, and the junction field-effect transistor region in an on-state can decrease a resist of a gate region, such that an electric current can easily flow from the source to the drain through the junction field-effect transistor region, thereby increasing the dielectric withstanding voltage of the power element.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 (FIG. 1A and FIG. 1B) is a schematic flowchart of a manufacturing method for a power element according to one embodiment of the present disclosure;

FIG. 2 to FIG. 6 are schematic views of steps corresponding to the embodiment shown in FIG. 1A and FIG. 1B;

FIG. 7 is a schematic partial top view of a power element according to one embodiment of the present disclosure;

FIG. 8 is a schematic cross-sectional view of the embodiment shown in FIG. 7; and

FIG. 9 is a schematic cross-sectional view of a power element according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

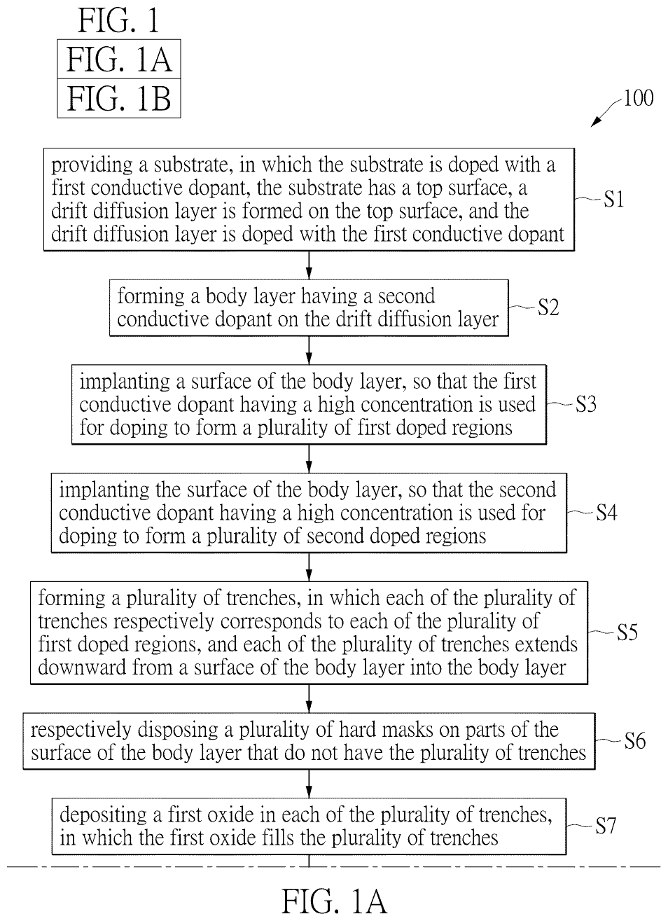

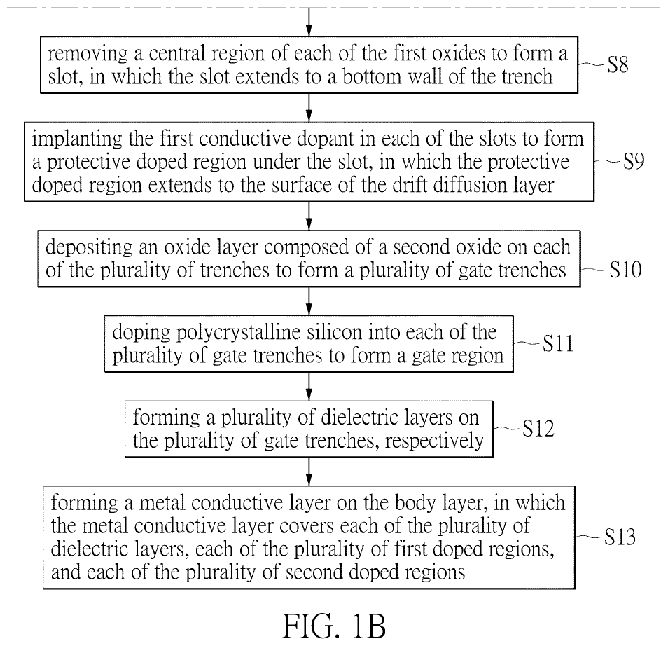

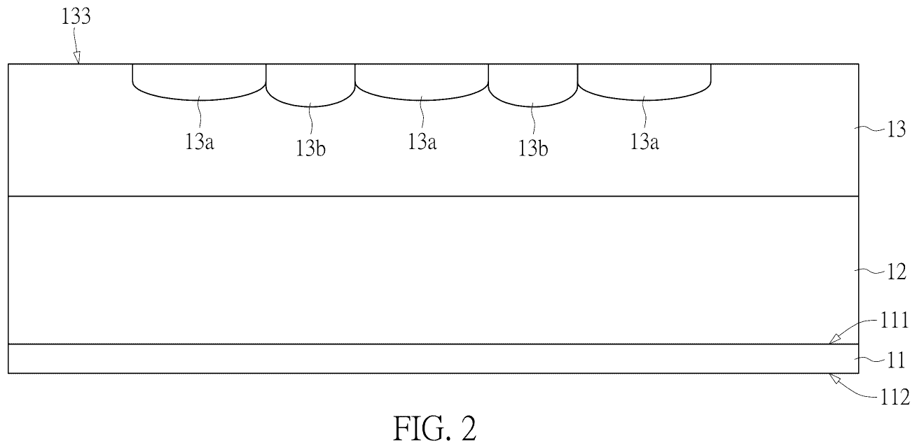

Referring to FIG. 1 to FIG. 6, FIG. 1 (FIG. 1A and FIG. 1B) is a schematic flowchart of a manufacturing method for a power element 100 according to one embodiment of the present disclosure, and FIG. 2 to FIG. 6 are schematic diagrams of steps corresponding to the embodiment shown in FIG. 1A and FIG. 1B. The manufacturing method for a power element 100 includes steps S1 to S13.

As shown in FIG. 2, step S1 includes: providing a substrate 11, and the substrate 11 is doped with a first conductive dopant. The substrate 11 has a top surface 111, and a drift diffusion layer 12 is formed on the top surface 111. The drift diffusion layer 12 is doped with the first conductive dopant. Step S2 includes: form a body layer 13 having a second conductive dopant on the drift diffusion layer 12. Step S3 includes: implanting a surface 133 of the body layer 13 so that the first conductive dopant having a high concentration is used for doping to form a plurality of first doped regions 13a. Step S4 includes: implanting the surface 133 of the body layer 13, so that the second conductive dopant having a high concentration is used for doping to form a plurality of second doped regions 13b. Any of the plurality of second doped regions 13b is located between two adjacent ones of the plurality of first doped regions 13a.

In certain embodiments, forming the body layer 13 is implanting the second conductive dopant (i.e. forming a well layer). The drift diffusion layer 12 may also be doped with the second conductive dopant to form an epitaxial layer.

In certain embodiments, the concentration of the body layer 13 is from 1×10¹⁶ cm⁻³ to 1×10¹⁸ cm⁻³.

According to certain embodiments, the substrate 11 is a silicon carbide (SiC) substrate 11. A bottom surface of the substrate 11 is a drain. According to certain embodiments, the first conductive dopant is an N-type dopant, and the second conductive dopant is a P-type dopant. However, the present disclosure is not limited thereto. According to other embodiments, the first conductive dopant is a P-type dopant, and the second conductive dopant is an N-type dopant. After steps S1 to S4 are performed, the structure of the power element (unfinished) is as shown in FIG. 2.

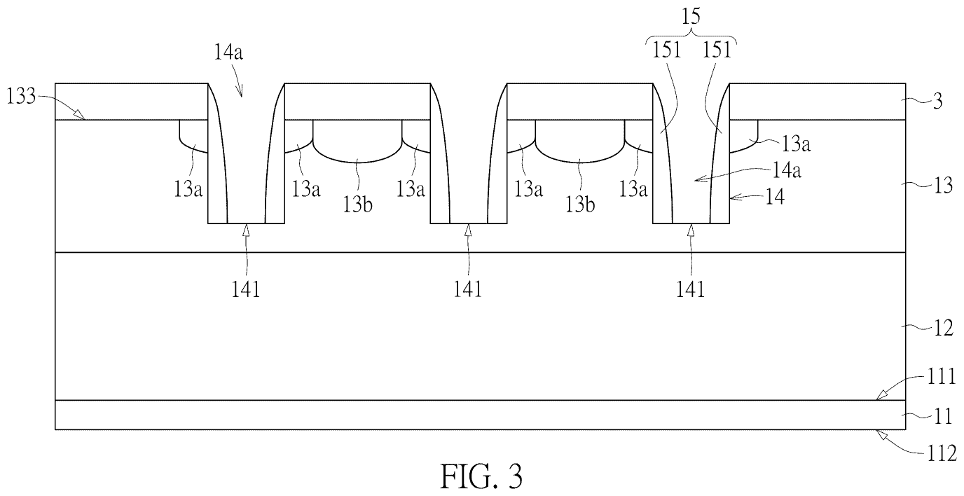

As shown in FIG. 3, steps S5 to S8 are described. Step S5 includes: forming a plurality of trenches 14. Each of the plurality of trenches 14 respectively corresponds to each of the plurality of first doped regions 13a. Each of the plurality of trenches 14 extends downward from the surface 133 of the body layer 13 into the body layer 13. Step S6 includes: respectively disposing a plurality of hard masks 3 on parts of the surface of the body layer 13 that do not have the plurality of trenches 14. Step S7 includes: depositing a first oxide 15 in each of the plurality of trenches 14, and the first oxides 15 fill the plurality of trenches 14. Step S8 includes: removing a central region of each of the first oxides 15 to form a slot 14a, in which the slot 14a extends to a bottom wall 141 of the trench 14.

According to the embodiment shown in FIG. 3, the bottom wall 141 of the trench 14 is located in the body layer 13 and is not in contact with the drift diffusion layer 12. The first oxide 15 is, for example, silicon dioxide (SiO₂). After the central region of the first oxide 15 is removed, the remaining portion of the first oxide 15 becomes sidewalls 151 in the trench 14 to cover a portion of the bottom wall 141. The procedure of depositing the first oxide 15 may be chemical vapor deposition or physical vapor deposition, and the present disclosure is not limited thereto. The aforementioned removal of the central region of the first oxide 15 may be performed by etching.

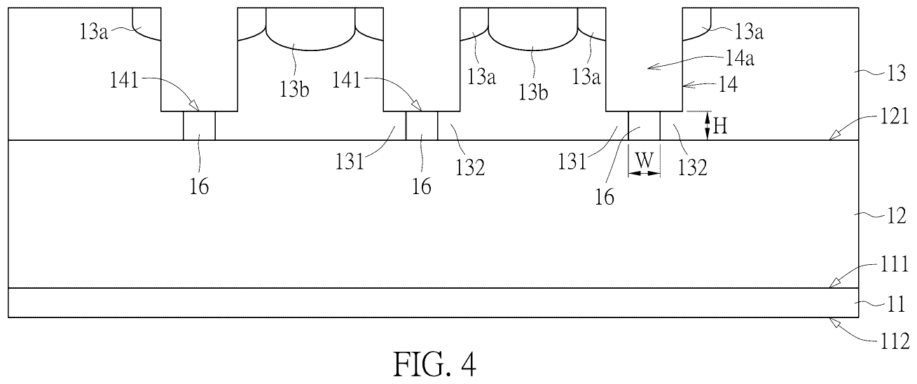

As shown in FIG. 4, step S9 includes: implanting the first conductive dopant in each of the slots 14a to form a protective doped region 16 under the bottom wall 141 of the slot 14a, in which the protective doped region 16 extends to the surface 121 of the drift diffusion layer 12 and corresponds to the bottom wall 141 of the trench 14, as shown in FIG. 4. A first region 131 and a second region 132 are respectively defined on two sides of the body layer 13 of the protective doped region 16. The first region 131, the protective doped region 16, and the second region 132 are located between the bottom wall 141 of the trench 14 and the surface 121 of the drift diffusion layer 12 to form a junction field-effect transistor region (JEFT).

Reference is further made to FIG. 3. In the embodiment shown in FIG. 4, due to the shielding of the sidewalls 151, after implanting the first conductive dopant, a width of the protective doped region 16 is smaller than a width of the trench 14. It should be noted that the present disclosure does not limit a depth H and a width W of the protective doped region 16, which are determined by a concentration of the body layer 13, a concentration of the protective doped region 16, and a withstand voltage requirements of the power element.

In certain embodiments, the concentration of the protective doped region 16 is greater than the concentration of the body layer 13, and the concentration of the body layer 13 is greater than the concentration of the drift diffusion layer 12.

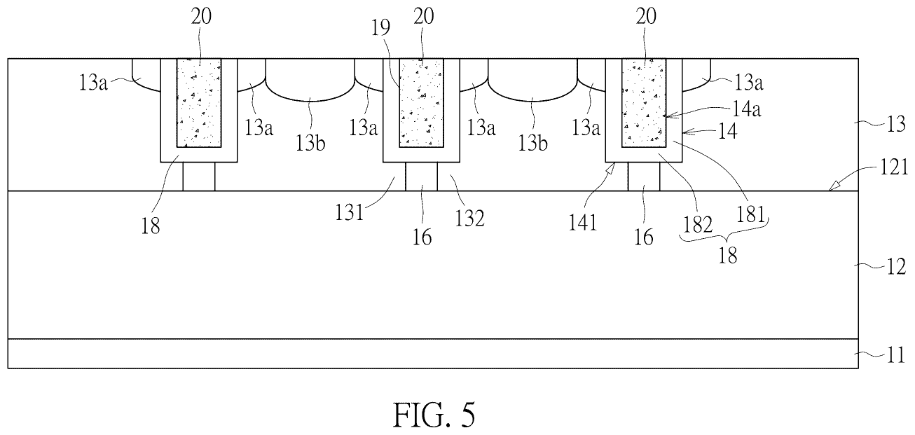

As shown in FIG. 5, step S10 and step S11 are described herein. Step S10 includes: depositing an oxide layer 18 composed of a second oxide on each of the plurality of trenches 14 to form a plurality of gate trenches 19. Step S11 includes: doping polycrystalline silicon 20 into each of the plurality of gate trenches 19 to form a gate region. Each of the gate trenches 19 has two side oxide layers 181 and a bottom oxide layer 182.

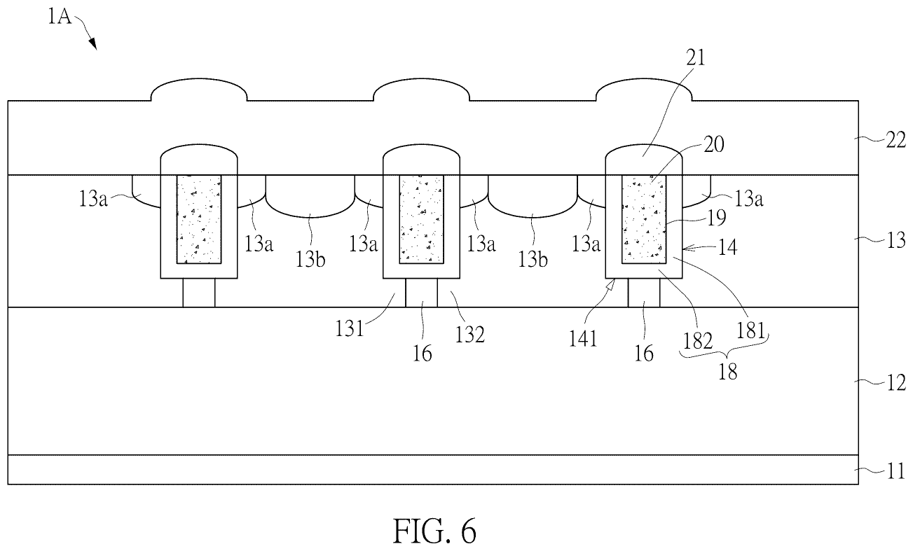

As shown in FIG. 6, step S12 and step S13 are described herein. Step S12 includes: forming a plurality of dielectric layers 21 on each gate trench 19 respectively. Step S13 includes: form a metal conductive layer 22 on the body layer 13. The metal conductive layer 22 covers each of the plurality of dielectric layers 21, each of the plurality of first doped regions 13a, and each of the plurality of second doped regions 13b. After step S12 and step S13 are performed, the manufacturing of the power element is completed, as shown in FIG. 6. According to this embodiment, the metal conductive layer 22 is used as a source.

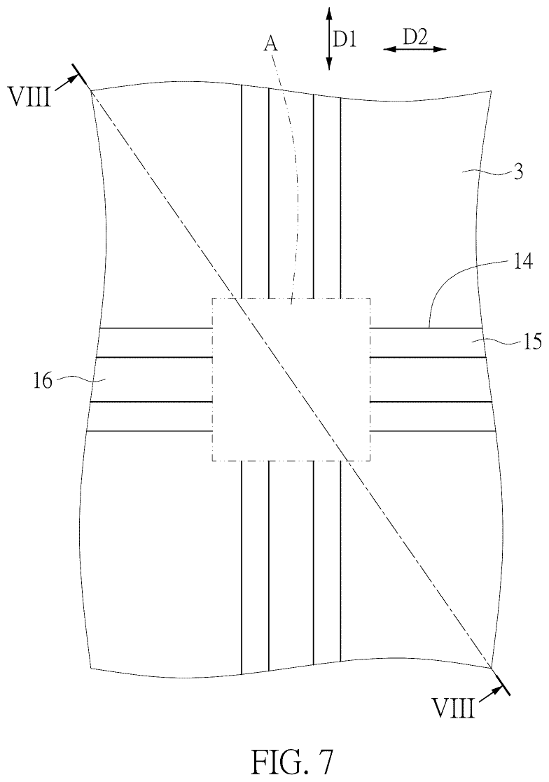

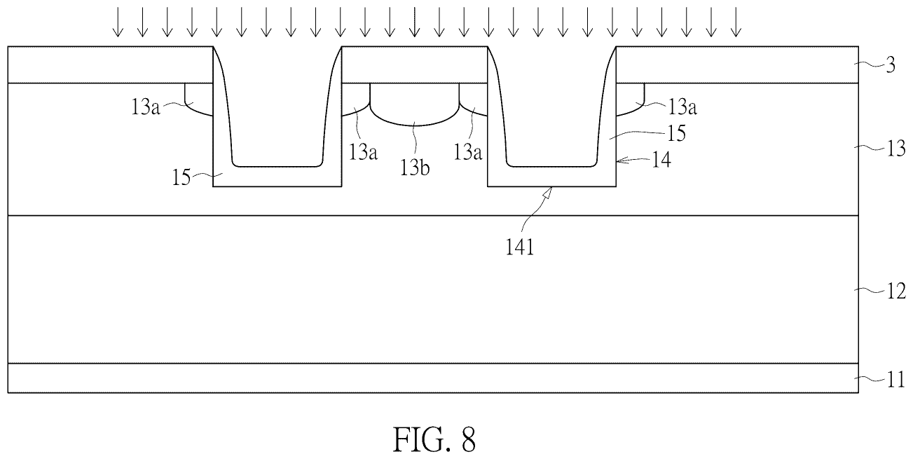

Referring to FIG. 7 and FIG. 8, FIG. 7 is a schematic partial top view of a power element according to one embodiment of the present disclosure, and FIG. 8 is a schematic cross-sectional view of the embodiment shown in FIG. 7. From a top view, each of the trenches 14 extends along a first direction D1 to define a first trench. The manufacturing method for a power element 100 further includes forming a plurality of additional trenches, and each of the additional trenches extends along a second direction D2 to define a second trench. A junction area A is defined on an intersection of each of the first trenches and each of the second trenches. In the aforementioned process of removing the central region of each of the first oxides 15 to form a slot 14a, the slot 14a does not extend to the bottom wall 141 of the trench 14 within the junction area A. In this way, after doping with the first conductive dopant, within the junction area A, due to the shielding of the first oxide 15 in the trench 14, the protective doped region 16 is not present under the bottom wall 141. If the junction area A has a protective doped region 16, the width of the protective doped region 16 will be large, and the electric field will also be unbalanced. Based on the consideration of withstanding voltage, and preventing damage dealt to the power elements, the protective doped region 16 is not manufactured in the junction area A (that is, the junction area A does not have the junction field-effect transistor region), as shown in FIG. 8.

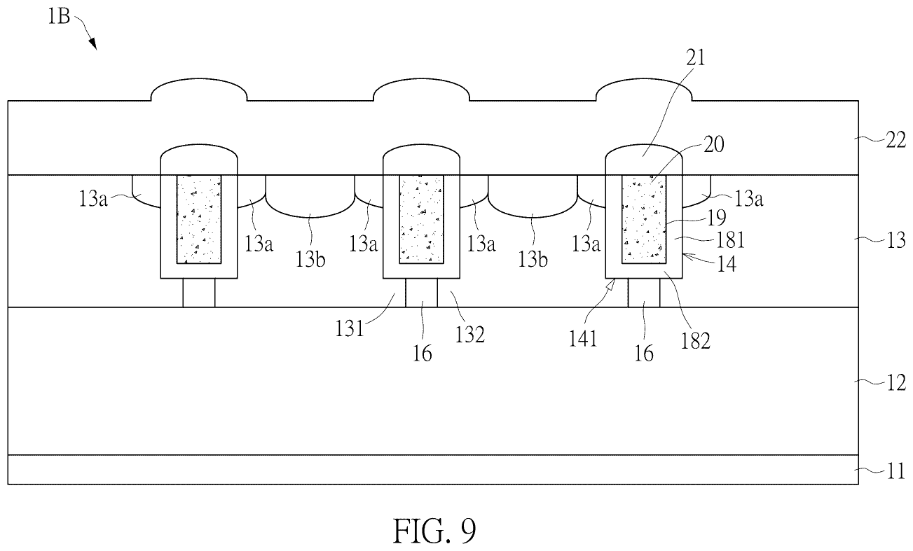

Referring to FIG. 9, FIG. 9 is a schematic cross-sectional view of a power element according to one embodiment of the present disclosure. The power element includes: a substrate 11, a drift diffusion layer 12, a body layer 13, a plurality of gate trenches 19, polycrystalline silicon 20, a plurality of first doped regions 13a, a plurality of second doped regions 13b, a plurality of dielectric layers 21, and a metal conductive layer 22. The substrate 11 has a first conductive dopant. The drift diffusion layer 12 is located on a top surface 111 of the substrate 11 and has the first conductive dopant. The body layer 13 is located on the drift diffusion layer 12. The body layer 13 has a second conductive dopant. An implantation surface is defined on a surface of the body layer 13. Each of the gate trenches 19 has two side oxide layers 181 and a bottom oxide layer 182. Polycrystalline silicon 20 is respectively filled in each of the gate trenches 19 to form a plurality of gate regions. The plurality of first doped regions 13a are located under the implantation surface and are respectively located on two sides of each of the gate trenches 19. Each of the first doped regions 13a has a high concentration of the first conductive dopant. The plurality of second doped regions 13b are located under the implantation surface, each of the second doped regions 13b is located between two adjacent ones of the first doped regions 13a, and each of the second doped regions 13b has a high concentration of the second conductive dopant. The plurality of protective doped regions 16 are located in the body layer 13. Two ends of each of the protective doped regions 16 are respectively connected to a bottom wall 141 of a corresponding one of the gate trenches 19 and the surface of the drift diffusion layer 12, corresponding to the bottom wall 141 of the gate trench 19. A first region 131 and a second region 132 are respectively defined on two sides of the body layer 13 of the protective doped region 16. The first region 131, the protective doped region 16, and the second region 132 form a junction field-effect transistor region. The plurality of dielectric layers 21 are located on each of the gate trenches 19, respectively. The metal conductive layer 22 is located on the body layer 13. The metal conductive layer 22 covers each of the dielectric layers 21, each of the first doped regions 13a, and each of the second doped regions 13b.

Details regarding “the substrate 11, the drift diffusion layer 12, the body layer 13, the gate trenches 19, the polycrystalline silicon 20, the first doped regions 13a, the second doped regions 13b, the dielectric layers 21, and the metal conductive layer 22” can be referred to in the above descriptions.

Reference is further made to FIG. 7 and FIG. 8. In certain embodiments, from a top view, each of the gate trenches 19 of the power element extends along the first direction D1 to define the first trench. The power element further includes a plurality of additional gate trenches 19, and each of the additional gate trenches 19 extends along the second direction D2 to define a second trench. A junction area A is defined on an intersection of each of the first trenches and each of the second trenches. Within the junction area A, the protective doped region 16 is not present under the bottom wall 141 of each of the gate trenches 19. Details regarding “junction area A” and “the protective doped region 16 being not present under the bottom wall 141 of each of the gate trenches 19” can be referred to in the above descriptions.

It should be noted that, the present disclosure does not limit the depth (thickness) of the body layer, the gate trench, and the protective doped region, and does not limit the width of the gate trench and the protective doped region. The depth (thickness) and concentration of the body layer, the gate trench, and the protective doped region are matched to each other and are determined by the user specifications.

### Beneficial Effects of the Embodiments

In conclusion, one of the beneficial effects of the present disclosure is that, in the power element and the manufacturing method for the power element provided by the present disclosure, by virtue of “forming a plurality of trenches,” “implanting the first conductive dopant in each of the slots to form a protective doped region under the slot,” and “the first region, the protective doped region, and the second region form a junction field-effect transistor region,” a manufacturing process of the power element can be simplified, and a doping concentration of the entire protective doped region is more uniform.

Furthermore, another one of the beneficial effects of the present disclosure is that, in the power element and the manufacturing method for the power element provided by the present disclosure, by virtue of “the first region, the protective doped region, and the second region of the power element form a junction field-effect transistor region,” the junction field-effect transistor region in an off-state can decrease an electric field at a bottom portion of the gate trenches, and the junction field-effect transistor region in an on-state can decrease a resist of a gate region, such that an electric current can easily flow from the source to the drain through the junction field-effect transistor region, thereby increasing the dielectric withstanding voltage of the power element.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method for a power element, comprising:
providing a substrate, wherein the substrate is doped with a first conductive dopant, the substrate has a top surface, a drift diffusion layer is formed on the top surface, and the drift diffusion layer is doped with the first conductive dopant;
forming a body layer having a second conductive dopant on the drift diffusion layer;
implanting a surface of the body layer, so that the first conductive dopant having a high concentration is used for doping to form a plurality of first doped regions, and implanting the surface of the body layer, so that the second conductive dopant having a high concentration is used for doping to form a plurality of second doped regions, wherein any of the plurality of second doped regions is located between two adjacent ones of the plurality of first doped regions;
forming a plurality of trenches, wherein each of the plurality of trenches respectively corresponds to each of the plurality of first doped regions, and each of the plurality of trenches extends downward from a surface of the body layer into the body layer;
respectively disposing a plurality of hard masks on parts of the surface of the body layer that do not have the plurality of trenches;
depositing a first oxide in each of the plurality of trenches, wherein the first oxide fills the plurality of trenches;
removing a central region of each of the first oxides to form a slot, wherein the slot extends to a bottom wall of the trench;
implanting the first conductive dopant in each of the slots to form a protective doped region under the slot, wherein the protective doped region extends to the surface of the drift diffusion layer; wherein a first region and a second region are respectively defined on two sides of the protective doped region, and the first region, the protective doped region, and the second region are located between the bottom wall of the trench and the surface of the drift diffusion layer to form a junction field-effect transistor region;
depositing an oxide layer composed of a second oxide on each of the plurality of trenches to form a plurality of gate trenches;
doping polycrystalline silicon into each of the plurality of gate trenches to form a gate region;
forming a plurality of dielectric layers on the plurality of gate trenches, respectively; and
forming a metal conductive layer on the body layer, wherein the metal conductive layer covers each of the plurality of dielectric layers, each of the plurality of first doped regions, and each of the plurality of second doped regions.

2. The manufacturing method according to claim 1, wherein forming the body layer includes implanting the second conductive dopant, or using the second conductive dopant for doping on the drift diffusion layer to form an epitaxial layer.

3. The manufacturing method according to claim 1, wherein a concentration of the protective doped region is greater than a concentration of the body layer, and the concentration of the body layer is greater than a concentration of the drift diffusion layer.

4. The manufacturing method according to claim 1, wherein the substrate is a silicon carbide substrate, the first conductive dopant is an N-type dopant, and the second conductive dopant is a P-type dopant.

5. The manufacturing method according to claim 1, wherein, from a top view, each of the plurality of trenches extends along a first direction to define a first trench, and the manufacturing method for the power element further comprises forming a plurality of additional trenches, each of the plurality of additional trenches extends along a second direction to define a second trench, wherein a junction area is defined on an intersection of each of the first trenches and each of the second trenches; wherein, in the process of removing a central region of each of the first oxides to form a slot, the slot does not extend to the bottom wall of the trench within the junction area.

6. A power element, comprising:
a substrate having a first conductive dopant;
a drift diffusion layer located on a top surface of the substrate, wherein the drift diffusion layer has the first conductive dopant;
a body layer located on the drift diffusion layer, wherein the body layer has a second conductive dopant, and an implantation surface is defined on a surface of the body layer;
a plurality of gate trenches, wherein each of the gate trenches has two side oxide layers and a bottom oxide layer;
polycrystalline silicon respectively filled in each of the plurality of gate trenches to form a plurality of gate regions;
a plurality of first doped regions located under the implantation surface and respectively located on two sides of each of the gate trenches, wherein each of the plurality of first doped regions has a high concentration of the first conductive dopant;
a plurality of second doped regions located under the implantation surface, wherein each of the plurality of second doped regions is located between two adjacent ones of the plurality of first doped regions, and each of the plurality of second doped regions has a high concentration of the second conductive dopant;
a plurality of protective doped regions located in the body layer, wherein two ends of each of the plurality of protective doped regions are respectively connected to a bottom wall of a corresponding one of the gate trenches and the surface of the drift diffusion layer; wherein a first region and a second region are respectively defined on two sides of each of the plurality of protective doped region, and the first region, the protective doped region, and the second region are located between the bottom wall of the gate trench and the surface of the drift diffusion layer to form a junction field-effect transistor region;
a plurality of dielectric layers located on the plurality of gate trenches, respectively; and
a metal conductive layer located on the body layer, wherein the metal conductive layer covers each of the plurality of dielectric layers, each of the plurality of first doped regions, and each of the plurality of second doped regions.

7. The power element according to claim 6, wherein the body layer is a well layer or an epitaxial layer.

8. The power element according to claim 6, wherein a concentration of the protective doped region is greater than a concentration of the body layer, and the concentration of the body layer is greater than a concentration of the drift diffusion layer.

9. The power element according to claim 6, wherein the substrate is a silicon carbide substrate, the first conductive dopant is an N-type dopant, and the second conductive dopant is a P-type dopant.

10. The power element according to claim 6, wherein, from a top view, among the plurality of gate trenches, a first trench is defined by each of the plurality of gate trenches that extends along a first direction, and a second trench is defined by each of the plurality of gate trenches that extends along a second direction, wherein a junction area is defined on an intersection of each of the first trenches and each of the second trenches; wherein the protective doped regions are not present below the bottom walls of the gate trenches within the junction area.
